(19) United States
(12) Patent Application Publication
(10) Pub. No.: US 2005/0124137 A1
(43) Pub. Date: Jun. 9, 2005

(54) Semiconductor substrate and manufacturing method therefor

(75) Inventor: Takao Yonehara, Kanagawa-ken (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo, JP (US)

(21) Appl. No.: 11/039,285

(22) Filed: Jan. 19, 2005

Related U.S. Application Data
(63) Continuation of application No. PCT/JP04/06178, filed on Apr. 28, 2004.

(30) Foreign Application Priority Data
May 7, 2003 (JP) 2003-128917

(51) Int. Cl. H01L 21/30; H01L 21/46; H01L 21/44

(52) U.S. Cl. 438/455; 438/458

(57) ABSTRACT

The first step of implanting ions in the first substrate which has a gallium arsenide layer on a germanium member and forming an ion-implanted layer in the first substrate, the second step of bonding the first substrate to the second substrate to form a bonded substrate stack, and the third step of dividing the bonded substrate stack at the ion-implanted layer are performed, thereby manufacturing a semiconductor substrate.

### TECHNICAL FIELD

The present invention relates to a semiconductor substrate and a manufacturing method therefor and, more particularly, to a semiconductor substrate which has a gallium arsenide layer and a manufacturing method therefor.

### BACKGROUND ART

A device on a compound semiconductor substrate made of gallium arsenide and other materials has for example high performance, high speed and good light-emitting properties. The compound semiconductor substrate, however, is expensive and has low mechanical strength, and is difficult to manufacture a large-area substrate.

Under these circumstances, attempts have been made to heteroepitaxially grow a compound semiconductor on a silicon substrate which is inexpensive, has a high mechanical strength, and can form a large-area substrate. For example, Japanese Patent No. 3,257,624 discloses a method of obtaining a large-area semiconductor substrate by heteroepitaxially growing a compound semiconductor layer on a silicon substrate, implanting ions in the silicon substrate, bonding the silicon substrate to another substrate, heating the ion-implanted layer and causing it to collapse, and dividing the bonded substrate stack. Such a method needs to relax mismatch between the lattice constant of silicon and that of the compound semiconductor to obtain good crystallinity, depending on the specifications of a required compound semiconductor substrate.

Japanese Patent No. 2,877,800 discloses a method of obtaining a compound semiconductor substrate by growing a compound semiconductor layer on a porous silicon layer formed on a silicon substrate, bonding the silicon substrate to another substrate, cutting the porous silicon layer with a jet of a fluid, and dividing the bonded substrate stack.

In the manufacturing method disclosed in Japanese Patent No. 2,877,800, the porous silicon layer between the silicon and the compound semiconductor relaxes mismatch between the lattice constant of silicon and that of the compound semiconductor to some degree to form a heteroepitaxial layer. It is difficult to eliminate the mismatch between the lattice constant of the porous silicon and that of the compound semiconductor, and thus the resultant compound semiconductor may have poor crystallinity. The specifications of some required compound semiconductor devices may limit the range of applications of a compound semiconductor substrate formed by such a manufacturing method, and the compound semiconductor devices may not sufficiently exhibit their superiority.

### DISCLOSURE OF INVENTION

The present invention has been made on the basis of the above-mentioned consideration, and has as its object to provide a method of manufacturing a semiconductor substrate which sufficiently exhibits its superiority as a compound semiconductor device and can ensure good economy.

According to the present invention, there is provided a semiconductor substrate manufacturing method, characterized by comprising a first step of implanting ions in a first substrate which has a gallium arsenide layer on a germanium member and forming an ion-implanted layer in the first substrate, a second step of bonding the first substrate to a second substrate to form a bonded substrate stack, and a third step of dividing the bonded substrate stack at the ion-implanted layer.

According to a preferred embodiment of the present invention, the gallium arsenide layer is preferably formed by epitaxial growth. Also, the first step may comprise a step of forming a compound semiconductor layer on the gallium arsenide layer.

According to a preferred embodiment of the present invention, the ions preferably include one of hydrogen ions and ions of a rare gas.

According to a preferred embodiment of the present invention, the third step preferably comprises a step of dividing the bonded substrate stack at the ion-implanted layer by annealing the bonded substrate stack.

According to a preferred embodiment of the present invention, the third step preferably comprises a step of dividing the bonded substrate stack at the ion-implanted layer by a jet of a fluid or a static pressure.

According to a preferred embodiment of the present invention, the third step preferably comprises a step of dividing the bonded substrate stack at the ion-implanted layer by inserting a member in the ion-implanted layer.

According to a preferred embodiment of the present invention, the manufacturing method preferably further comprises a step of removing a part of the ion-implanted layer left on a part of the gallium arsenide layer, which has been transferred to the second substrate after the third step.

According to a preferred embodiment of the present invention, the manufacturing method preferably further comprises a step of planarizing a surface of the germanium member obtained by division in the division step and reusing the germanium member in the first step.

Other features and advantages of the present invention will be apparent from the following description taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a view for explaining a semiconductor substrate manufacturing method according to a preferred embodiment of the present invention;

FIG. 2 is a view for explaining the semiconductor substrate manufacturing method according to the preferred embodiment of the present invention;

FIG. 3 is a view for explaining the semiconductor substrate manufacturing method according to the preferred embodiment of the present invention;

FIG. 4 is a view for explaining the semiconductor substrate manufacturing method according to the preferred embodiment of the present invention;

FIG. 5 is a view for explaining the semiconductor substrate manufacturing method according to the preferred embodiment of the present invention;

FIG. 6 is a view for explaining the semiconductor substrate manufacturing method according to the preferred embodiment of the present invention; and

FIG. 7 is a view for explaining the semiconductor substrate manufacturing method according to the preferred embodiment of the present invention;

### BEST MODE FOR CARRYING OUT THE INVENTION

A preferred embodiment of the present invention will be described with reference to the accompanying drawings.

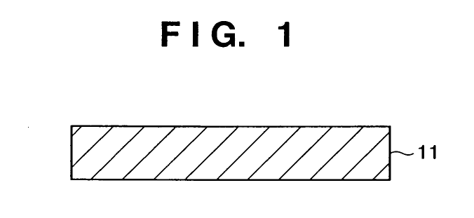

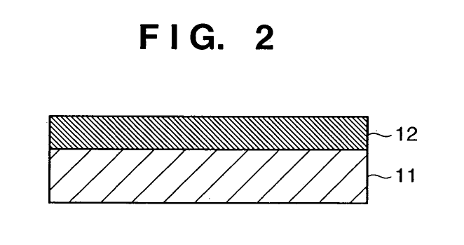

FIGS. 1 to 7 are views for explaining a substrate manufacturing method according to the preferred embodiment of the present invention. In the step shown in FIG. 1, a germanium member 11 is prepared. Then, in the step shown in FIG. 2, a gallium arsenide layer 12 is formed on the surface of the germanium member 11 by epitaxial growth. Since mismatch between the lattice constant of germanium and that of gallium arsenide is small, a gallium arsenide layer with good crystallinity can be formed on the germanium member 11. Epitaxial growth allows the gallium arsenide layer to have a uniform thickness.

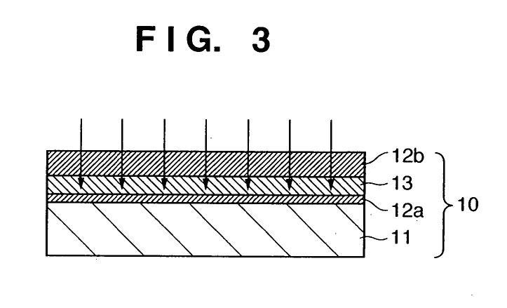

In the step shown in FIG. 3, hydrogen ions are implanted in the surface of the gallium arsenide layer 12 shown in FIG. 2. An ion-implanted layer 13 is formed in the gallium arsenide layer 12, thereby forming a first substrate 10. In addition to hydrogen ions, ions of a rare gas such as helium, neon, argon, krypton, xenon, or the like may be used alone or in combination in the implantation. Though not shown, an insulating layer is formed on the surface of the gallium arsenide layer 12, prior to the ion implantation. The ion-implanted layer 13 can be formed in at least one of the germanium member 11 and the gallium arsenide layer 12.

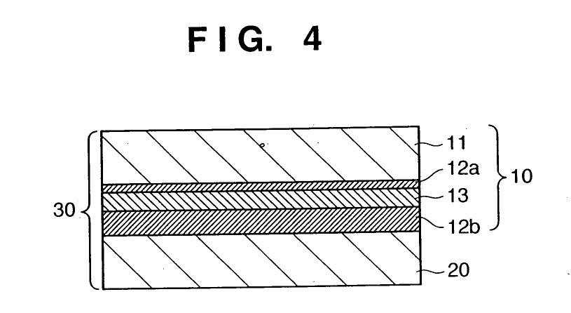

In the step shown in FIG. 4, a second substrate 20 is bonded to the surface of the first substrate 10 to form a bonded substrate stack 30. Typically, a silicon substrate or a substrate obtained by forming an insulating layer such as an SiO₂ layer on its surface can be adopted as the second substrate 20. Also any other substrate such as an insulating substrate (e.g., a glass substrate) may be used as the second substrate 20.

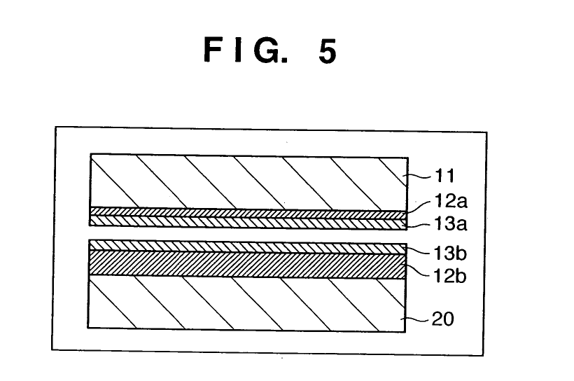

In the step shown in FIG. 5, the bonded substrate stack 30 is divided at the ion-implanted layer 13 into two substrates. The ion-implanted layer 13 has highly concentrated microcavities, microbubbles, distortions, or defects, and is more fragile than the remaining portion of the bonded substrate stack 30. This division can be performed by, for example, annealing the bonded substrate stack 30. Alternatively, the division can be performed by, for example, a method of using a fluid. As the method, a method of forming a jet of a fluid (liquid or gas) and injecting the jet to the separation layer 12, a method which utilizes the static pressure of a fluid, or the like may preferably be used. Out of jet injection methods, a method using water as the fluid is called a water jet method. Alternatively, the division can be performed by inserting a solid member such as a wedge into the separation layer 12.

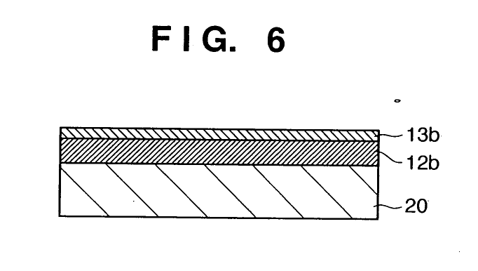

In the step shown in FIG. 6, an ion-implanted layer 13b left on a gallium arsenide layer 12b of the second substrate 20 is removed using an etchant or the like. At this time, the gallium arsenide layer 12b is preferably be used as an etching stopper layer. Then, a hydrogen annealing step, polishing step, or the like may be performed as needed to planarize the second substrate.

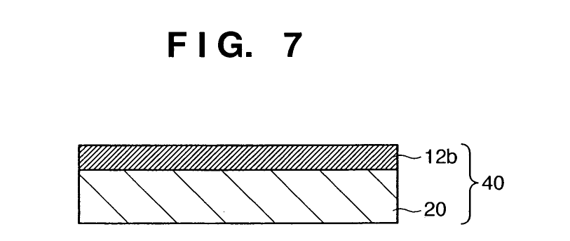

With the above-mentioned operation, a semiconductor substrate 40 shown in FIG. 7 is obtained. The semiconductor substrate 40 shown in FIG. 7 has the thin gallium arsenide layer 12b on its surface. The expression “thin gallium arsenide layer” is intended to mean a layer thinner than a general semiconductor substrate. To exhibit the superiority as a semiconductor device, the thickness of the gallium arsenide layer 12b preferably falls within a range of 5 nm to 5 μm. Another compound semiconductor layer of AlGaAs, GaP, InP, InAs, or the like can be formed on the gallium arsenide layer 12b, depending on the specifications of the semiconductor device.

After the division in the step shown in FIG. 5, an ion-implanted layer 13a or the like left on the germanium member 11 is removed using an etchant or the like. Then, the hydrogen annealing step, polishing step, or the like may be performed to planarize the surface of the germanium member. The planarized substrate can be reused as the germanium member 11 to be used in the step shown in FIG. 1. Repeated reuse of the germanium member 11 can greatly reduce the manufacturing cost of a semiconductor substrate.

As has been described above, the manufacturing method according to the present invention makes it possible to obtain a semiconductor substrate which has a gallium arsenide layer with a uniform thickness and good crystallinity. Also, the manufacturing method according to the present invention can greatly reduce the manufacturing cost of a semiconductor substrate with a gallium arsenide layer.

Therefore, according to the present invention, there can be provided a method of manufacturing a semiconductor substrate which sufficiently exhibits its superiority as a compound semiconductor device and can ensure good economy.

As many apparently widely different embodiments of the present invention can be made without departing from the spirit and scope thereof, it is to be understood that the invention is not limited to the specific embodiments thereof except as defined in the claims.

1. A semiconductor substrate manufacturing method, comprising:
a first step of implanting ions in a first substrate which has a gallium arsenide layer on a germanium member and forming an ion-implanted layer in the first substrate;
a second step of bonding the first substrate to a second substrate to form a bonded substrate stack; and
a third step of dividing the bonded substrate stack at the ion-implanted layer.

2. The manufacturing method according to claim 1, wherein the gallium arsenide layer is formed by epitaxial growth.

3. The manufacturing method according to claim 1, wherein the first step comprises a step of forming a compound semiconductor layer on the gallium arsenide layer.

4. The manufacturing method according to claim 1, wherein the ions include one of hydrogen ions and ions of a rare gas.

5. The manufacturing method according to claim 1, wherein the third step comprises a step of dividing the bonded substrate stack at the ion-implanted layer by annealing the bonded substrate stack.

6. The manufacturing method according to claim 1, wherein the third step comprises a step of dividing the bonded substrate stack at the ion-implanted layer by a jet of a fluid or a static pressure.

7. The manufacturing method according to claim 1, wherein the third step comprises a step of dividing the bonded substrate stack at the ion-implanted layer by inserting a member in the ion-implanted layer.

8. The manufacturing method according to claim 1, further comprising a step of removing a part of the ion-implanted layer left on a part of the gallium arsenide layer, which has been transferred to the second substrate after the third step.

9. The manufacturing method according to claim 1, further comprising a step of planarizing a surface of the germanium member obtained by division in the division step and reusing the germanium member in the first step.

10. A semiconductor substrate which is manufactured by a manufacturing method as defined in claim 1.
